(19) United States
(12) Patent Application Publication
(10) Pub. No.: US 2007/0164455 A1
(43) Pub. Date: Jul. 19, 2007

(54) Electronic device with bending wiring pattern

(75) Inventor: Noriyoshi Matsuura, Kawanishi-shi (JP)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONIC, N.V., EINDHOVEN (NL)

(21) Appl. No.: 10/596,758

(22) PCT Filed: Dec. 17, 2004
(86) PCT No.: PCT/IB04/52839

§ 371 Date: Jun. 23, 2006

(51) Int. Cl. H01L 23/52

(52) U.S. Cl. 257/784

(57) ABSTRACT

An object of the invention is to provide a form of bending wiring patterns whose wiring resistances can be as equal as possible based on a simple structure and to provide an electronic device based on the form. An electronic device having a substrate (100) on which a plurality of conductive lines (10) are formed, the conductive lines (10) having such patterns that the lines are straightly extended from their predetermined front ends is and there-after bend by turns in substantially the same direction for each predetermined interval P to further extend to the respective predetermined connection targets (30). The conductive lines (10) have their straightly-extending portions (10L) of varied line widths and a line width at a nearer position to a bending point (Q) of the line is larger than a line width at a farther position from the bending point (Q), so as to equalize at least resistance values of the straightly-extending portions (10L) of the conductive lines (10).

### TECHNICAL FIELD

The invention relates to an electronic device having bending wiring pattern, in particular to an electronic device having a number of electrically conductive lines having bending wiring patterns which are suitable especially for a display panel or the like.

### BACKGROUND ART

There has been long since known electronic substrates on which a plurality of traces are formed, the traces having such a pattern that the traces straightly extend from their respective front ends and bend by turns regularly to further extend to the respective connection targets (for example, see Patent Document 1).

In Patent Document 1, wiring widths of first wiring portions in the horizontal direction among data electrodes or scanning electrodes are wider than wiring widths of second wiring portions in the vertical direction among the electrodes, thereby reducing the pattern resistance of each of the electrodes. Differences are thus reduced between pattern resistance values due to differences between wiring lengths of the electrodes, thereby reducing unevenness in luminance (Paragraph numbers [0022] and [0024]).

This document also has a proposal that a compensating resistor is inserted between each electrode terminal and each electrode driver thereof to compensate differences between the pattern resistance values due to differences between wiring lengths of the data electrodes or scanning electrodes, while resistance values of the compensating resistors are set such that the sums of resistance values of the compensating resistors and pattern resistance values of the electrodes to which the compensating resistors are connected are equal to each other, resulting in compensation of the differences between pattern resistance values due to differences between wiring lengths of the elec trodes, and in reduction of luminance un-uniformity (Paragraph numbers [0022], [0023], [0025] and [0026]).

However, in the former form, the widths of the wiring portions in the horizontal direction are merely made larger than those of the wiring portions in the vertical direction and the resistance values are reduced across the board with respect to all the electrodes, whereby variations in resistance between the electrodes are suppressed, but it is not sufficient to obtain equal resistance values of the electrodes. Further, in the latter form, it is required to separately provide each individual compensating resistor set having its appropriate resistance value between an electrode terminal and the corresponding driver for each electrode, so the structure is made complicated and has disadvantages in respect of the number of components and manufacturing processes.

[Patent Document 1]

Japanese Patent Application Laid-Open No. 63198/98

### DISCLOSURE

### Object

An object of the invention is to provide a form of bending wiring patterns whose wiring resistances can be as equal as possible based on a simple structure and to provide an electronic device based on the form.

Another object of the invention is to provide an electronic device having a number of electrically conductive lines having bending wiring patterns which are suitable especially for a display panel or the like, in which the conductive lines use a form of bending wiring patterns whose wiring resistances can be as equal as possible based on a simple structure and which can equalize delays, amplitudes or other qualities of signals transmitted through the conductive lines.

### Constitution

In order to achieve the objects, an electronic device according to an aspect of the invention is an electronic device having a substrate on which a plurality of conductive lines are formed, the conductive lines having such patterns that the lines are straightly extended from their predetermined front ends and thereafter bend by turns in substantially the same direction for each predetermined interval to further extend to the respective predetermined connection targets, wherein the conductive lines have their straightly-extending portions of varied line widths and a line width at a nearer position to a bending point of the line is made larger than a line width at a farther position from the bending point, so as to equalize at least resistance values of the straightly-extending portions of the conductive lines.

According to this aspect, resistance values of the conductive lines are made equal based on variations in line width in the straightly-extending portion constituting the main part of the conductive line, and thereby, wiring resistance values can be made as equal as possible based on a simple structure. It is thus possible to equalize delays, amplitudes and/or other qualities of signals transmitted through the conductive lines.

In this aspect, the front ends of the conductive lines may be connected to inputs/outputs of driving circuitry or peripheral circuitry of the electronic device. By doing so, resistance values are uniformed in straightly-extending portions of the conductive lines from inputs/outputs of the driving circuitry or peripheral circuitry.

Further, the connection targets of the conductive lines may be a plurality of lines extending substantially in parallel to each other at predetermined intervals, or the bending angle may be substantially a right angle. In this way, it is possible to thoroughly exert the effects and advantages specific to the invention.

Furthermore, it is preferable that the device comprises a plurality of bus lines extending in parallel to each other at predetermined intervals in a display area defined by at least one and the other sides opposed to each other, the bus lines extending from a position of the one side to a position of the other side, wherein the straightly-extending portions are arranged in an area outside the display area adjacent to at least one of the one and the other sides. It is thereby possible to define an area suitable for an arrangement of the conductive lines having bending patterns according to the invention in an area except the display area on the substrate.

When the bus lines are row electrode lines or gate electrode lines, or column electrode lines or source electrode lines, a more preferred embodiment is obtained.

Moreover, the display area may be also defined by third and fourth sides opposed to each other and formed substantially perpendicularly to the one and the other sides, and the driving circuitry or peripheral circuitry is provided in an area outside the display area adjacent to at least one of the third and fourth sides, whereby it is possible to define an area suitable for an arrangement of the conductive lines having bending patterns according to the invention and an area suitable for an arrangement of the driving circuitry or peripheral circuitry.

### DESCRIPTION OF DRAWINGS

FIG. 1 is a schematic plan overview of a substrate used in an electronic device according to an embodiment of the invention;

FIG. 2 is a schematic partial enlarged view of conductive lines according to the embodiment of FIG. 1; and

FIG. 3 is a schematic partial enlarged view of conductive lines according to a modification in the invention.

### BEST MODE

Now a mode for curing out the present invention will be described in detail below by way of embodiments with reference to accompanying drawings.

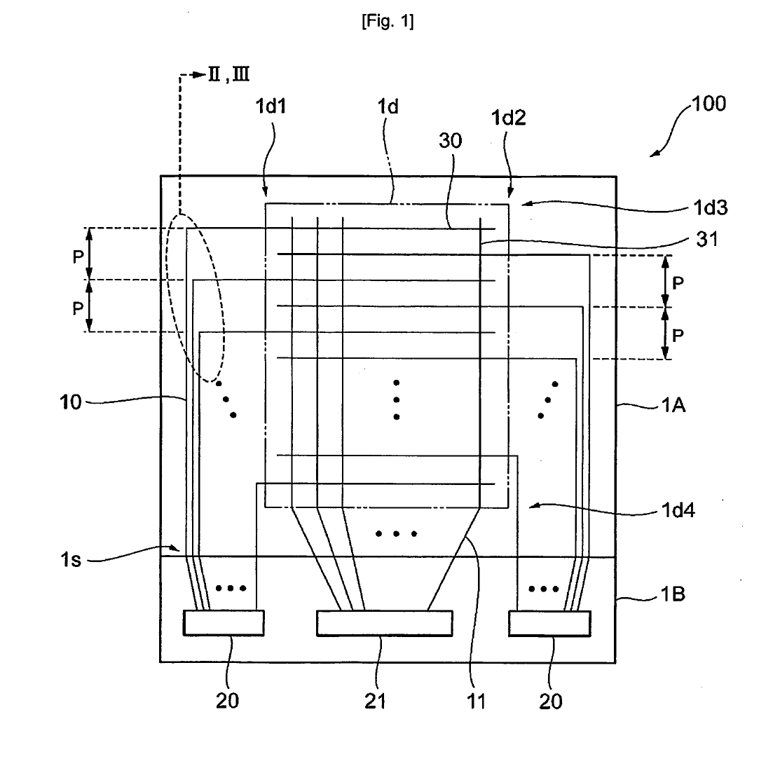

FIG. 1 shows a schematic plan overview of a substrate used in an electronic device according to an embodiment of the invention.

A substrate 100 in this embodiment is a liquid crystal display panel, and the liquid crystal display panel has a display-functional section 1A in which a display area 1d is defined in a substantially center portion of the portion 1A, and a driving-functional section 1B which is provided with driving circuits (or peripheral circuits) 20 to perform driving of each pixel of the display area 1d and other operations and which is provided adjacent to and side by side with the display-functional section 1A.

In the display-functional section 1A, a plurality of conductive lines 10 are formed on the sides of the display area 1d. The conductive lines 10 have such patterns that the lines straightly (upward in the figure) extend from their predetermined front ends 1s on the driving-functional section 1B side and bend by turns in substantially the same direction (rightward or leftward in the figure) every predetermined interval P to further extend to the respective predetermined connection targets on the display area 1d side. The front ends 1s of the conductive lines 10 are connected to inputs/outputs of the driving circuits 20 in the driving-functional section 1B. The connection targets of the conductive lines 10 are a plurality of bus lines 30 extending in parallel to one another at predetermined intervals in the display area 1d.

The bus lines 30 serve as row electrode lines in the display area 1d having one side (first side) 1d1 and the other side (second side) 1d2 opposed to each other in the left and right in the figure, and extend in parallel to one another at predetermined intervals from a position of the one side to a position of the other side of the rectangular display area 1d. Other bus lines 31 are formed intersecting the bus lines 30. The bus lines 31 serve as column electrode lines in the display area 1d, and extend in parallel to one another at predetermined intervals from one position to the other position between a third side 1d3 and a fourth side 1d4 of the rectangular display area, which are formed substantially at right angles to the first side 1d and the second side 1d2 and opposed to each other in the upper and lower positions in the figure.

In this embodiment, an active driving system is adopted which uses a thin-film transistor (TFT) as a pixel driving element, wherein the bus lines 30 and 31 are gate electrode lines and source electrode lines, respectively, and in general, the TFTs are formed corresponding to intersections of the bus lines 30 and 31. In addition, details of the structure and operation of the display area based on such an active driving system are left to other various publicly-known documents, and omitted herein.

The straightly-extending portions of the conductive lines 10 are arranged in an areas outside the display area 1d, which are adjacent to the first side 1d1 and second side 1d2 of the display area 1d. As shown in the figure, in the thus arranged conductive lines 10, conductive lines located more outwardly have their longer straightly-extending portions. Further, more inward conductive lines (i.e. near the display area 1d) are connected to bus lines 30 nearer to the driving circuits 20 (or driving-functional section 1B), and sequentially, conductive lines arranged more outwardly are connected to bus lines 30 farther from the driving circuits 20 (or diving-functional section 1B).

Conductive lines 11 connected to the bus lines 31 do not have bending patterns specific to the conductive lines 10, and connect the input/output ends of a driving-circuit 21 in the driving-functional section 1B and the bus lines 31 over the shortest possible distance.

As can be seen from FIG. 1, in this embodiment, the driving circuits 20 and 21 are formed in an area outside the display area 1d, adjacent to the fourth side 1d4 of the display area 1d, i.e. herein, in an area of the driving-functional section 1B. In this way, by forming circuits required for the liquid crystal display panel 100 only on the one side part area constituting the plane-outline of the liquid crystal display panel 100, it is possible to form the display area 1d efficiently. Further, such a form that the driving circuit is arranged only on one side may significantly be advantageous to some electronic devices to be used for some application.

Further, in this embodiment, the driving circuits 20 are separately arranged on both left and right sides of the driving-functional section 1B. Then, the conductive lines 10 connected to the circuits 20 are drawn from areas near the first side 1d1 and the second side 1d2 of the display area 1d to the display area, and connected to the bus lines 30 alternately from the left one and from the right one. In other words, such a form is adopted that in the up/down arrangement direction of the bus lines 30, a bus line 30 is connected to a conductive line 10 in the area near one of the first side 1d1 and the second side 1d2, and the adjacent next bus line 30 is connected to another conductive line 10 in the area near the other one of the first side 1d1 and the second side 1d2. It is thereby possible to make an interval P of bending points of the conductive lines 10 twice the interval of the bus lines 30, providing advantages to pattern formation of the conductive lines 10.

In this embodiment, the bus lines 30 serving as row electrodes are connected to the conductive lines 10 having bending patterns as described above, and the conductive lines 10 are formed in the manner as described below, whereby conductive line resistance values between outputs of the driving circuit 20 and inputs of the bus lines 30 are made all as equal as possible.

It is noted that the display-functional section 1A and the driving-functional section 1B may be formed in different substrate assemblies or in the same substrate assembly. For the case of the different substrate assemblies, there is a way that end portions of the conductive lines are exposed at the exterior on one of two opposed substrates (display-functional section 1A) sandwiching the liquid crystal medium, and the exposed end portions are coupled with conductive lines from the driving circuit 20 formed on a film substrate (driving-functional section 1B) such as a TAB film, using ACF (Anisotropic Conductive Film). On the other hand, for the case of the same substrate assembly, there is a way that two opposed substrates sandwiching the liquid crystal medium include the display-functional section 1A, one of the substrates is provided with an area (driving-functional section 1B) forming end portions of the conductive lines, and the driving circuit 20 connected to the end portions is mounted or formed on the area.

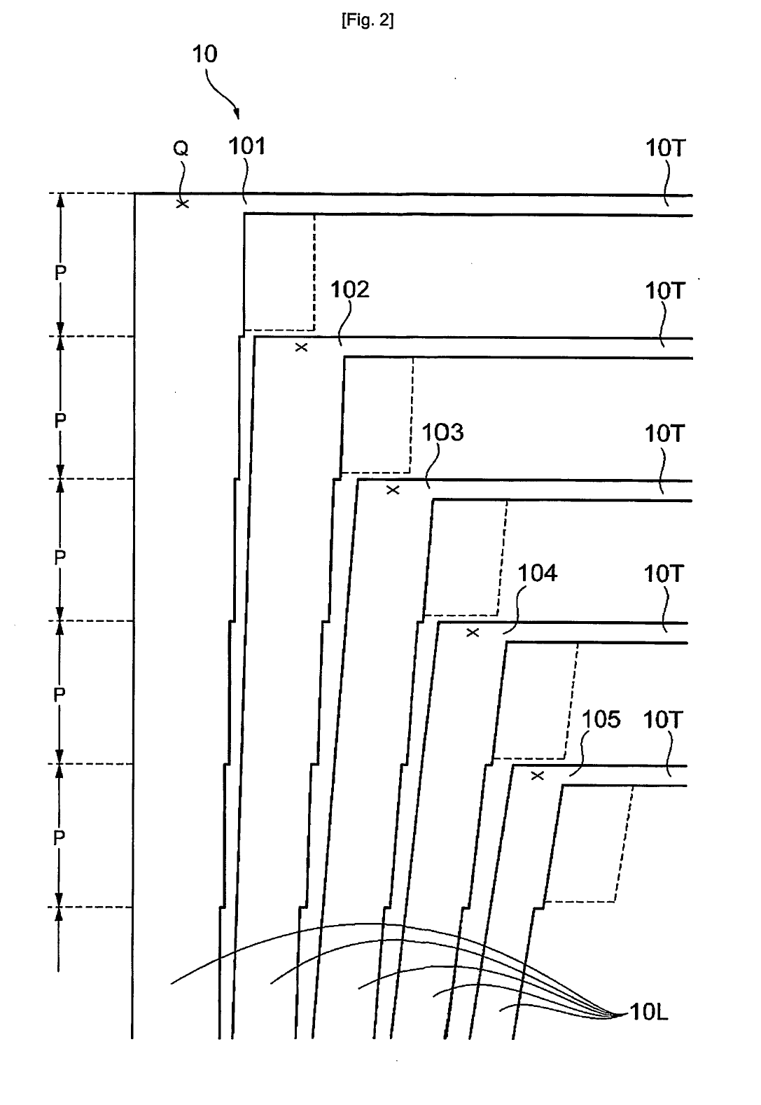

FIG. 2 shows a partial enlarged view of the conductive lines 10 to explain a more specific formation manner of the conductive lines 10.

FIG. 2 shows enlarged forms in the vicinity of bending points of the conductive lines 10 as shown in FIG. 1, as a representative formation manner. The outermost conductive line 101 has, in this example, such a form that the outer edge of the straightly-extending portion 10L is a straight line, and the inner edge has a shape of showing a step for each predetermined interval P. Such a form satisfies conditions that a line width in a position nearer to the bending point Q is larger than a line width in a position farther from the bending point Q, and in this embodiment, the width of the straightly-extending portion 10L of the conductive line 101 is varied for each predetermined interval P (or whenever the bending point Q of other conductive line appears), and the width is constant within the interval.

Similarly, other conductive lines 102, 103, . . . have the form satisfying the conditions that a line width in a position nearer to the bending position Q is larger than a line width in a position farther from the bending point Q, and the widths of the straightly-extending portions 10L of the conductive lines 101 are varied for each predetermined interval P (or whenever the bending point Q of other conductive line appears). But it is remarkable that the straightly shaped outer edges of the conductive lines 102, 103, . . . extend along a direction parallel to a line connecting corners each substantially forming a step of a step-shaped edge portion of the outwardly adjacent conductive line, unlike the conductive line 101 whose outer edge extends along the direction perpendicular to the arrangement direction (side-to-side direction in the figure) of the conductive lines 10.

These conductive lines 101, 102, 103, . . . are formed in such a manner that the line width of each straightly-extending portion 10L is provided with variations and its line width nearer to the bending point Q is greater than its line width farther from the point so as to equalize at least resistance values of the straightly-extending portions 10L, preferably, total resistance values of the straightly-extending portions 10L and the extending portions 10T after the bending. Generally, in order to obtain such equal resistance values, the average of the line widths of the straightly-extending portion 10L of a more outside conductive line is made larger than more inside conductive lines.

In this embodiment, an outward conductive line 10 long in drawing length has such a pattern that the width is increased as nearer the bending point Q. Such a pattern is advantageous to conductive lines that extend from their front ends and bend by turns toward the same direction for each predetermined interval. In other words, in the area where the conductive lines are arranged, there is ample empty space for drawing the bent conductive lines, and the empty space is conveniently available to increase widths of the other conductive lines bending in points farther from the bending point of a conductive line.

Moreover, although the average of line widths of the straightly-extending portion 10L of an outward conductive line is made larger than that of an inward conductive line, the width of the conductive line is increased as shown in FIG. 2 as a representative example using the empty space, so as to limit differences between averages of line widths of the straightly-extending portions 10L of the conductive lines to small values.

Table 1 shows an example in the case of setting the widths of the conductive lines 101-105 under predetermined conditions.

TABLE 1

| | Conductive | Conductive | Conductive | Conductive | Conductive | |
|---|---|---|---|---|---|---|
| | line 101 | line 102 | line 103 | line 104 | line 105 | Sum total |
| Interval P₅ | 0.23053 | 0.23053 | 0.23053 | 0.23053 | 0.07788 | 1 |
| Interval P₄ | 0.29414 | 0.29414 | 0.29414 | 0.11758 | | 1 |
| Interval P₃ | 0.40206 | 0.40206 | 0.19588 | | | 1 |
| Interval P₂ | 0.61803 | 0.38197 | | | | 1 |
| Interval P₁ | 1 | | | | | 1 |

One of the conditions in this case is that only the conductive lines 101-105 are target ones and the conductive lines 101-105 bend as for the intervals P₁, P₂, P₃, P₄ and P₅, respectively from the end of the outer conductive line 101. The other conditions are that the intervals P₁, P₂, P₃, P₄ and P₅ are equal to each other, and thicknesses and conductivities of the conductive lines are also equal to each other. In addition, values in columns in the table, indicated for each conductive line mean widths for the respective intervals of the conductive line when a width of the wiring area (sum of widths of all conductive lines) is 1. According to this example, if the intervals P₁ to P₅ are 1, the thicknesses of the conductive lines are 1, and their resistivities are 1, then any conductive lines will have a resistance of a value of 12.84.

There are other combinations of widths of the conductive lines for resistance equalization even under the same conditions, but it is expected that relatively low resistances can be obtained by making widths of conductive lines other than the innermost conductive line for each interval to be equal, as indicated in Table 1.

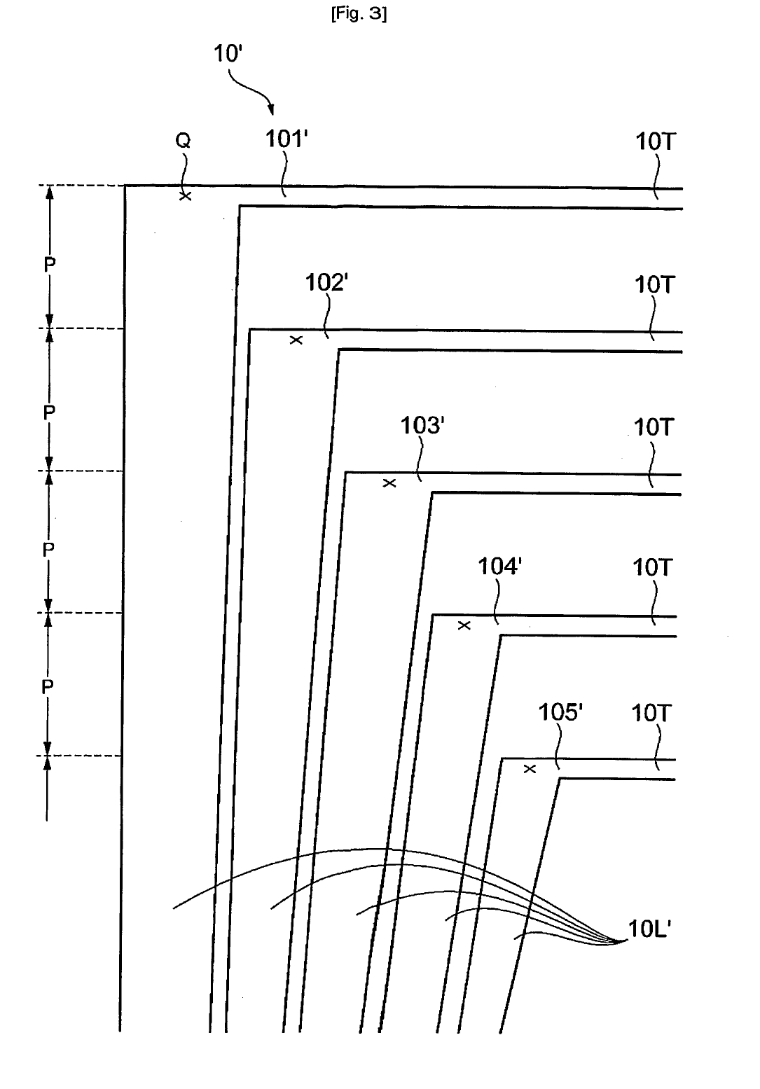

FIG. 3 shows a partial enlarged view of modified conductive lines 10′ to explain a more specific manner of formation of the conductive lines 10′.

Also in FIG. 3, enlarged shapes in the vicinity of bending points of the conductive lines are shown as a representative formation manner.

Conductive lines 101′, 102′, 103′, . . . in this embodiment have different forms from those shown in FIG. 2, and their inner edges are all made in the form of a straight line, while each straight line constituting the inner edge is not parallel to a straight line constituting the outer edge and is at a small angle to the outer straight line. More specifically, each conductive line has a form such that the width tapers toward the front end. The conductive lines of such a pattern have advantages in that spaces between the conductive lines are allowed to be kept constant, while facilitating pattern formation.

In the form of the conductive lines, the width of the straightly-extending portion 10L′ changes gradually over the whole length of the straightly-extending portion 10L′, and the width within a range of interval P is also varied. However, this form also satisfies such requirements that the line width varies in each of the straightly-extending portions and a line width in a position nearer to the bending point Q is formed larger than a line width in a position farther from the point Q so as to equalize at least respective resistance values in the straightly-extending portions in 101′, 102′, . . . Thus, the basic effects and advantages as described earlier are similarly obtained.

In addition, also in this from, it is possible to make full use of the empty space as described above.

According to the above-mentioned embodiments, it is achieved not only to suppress variations in resistance of conductive lines, but also to enable wiring resistance values of the lines to be as equal as possible with ease without any need of separately providing resistors individually set for resistance values, using only pattern formation of conductive lines.

Then, by using the bending wiring pattern form according to the invention in conductive lines of an electronic device, it is possible to equalize delays, amplitudes and/or other qualities of signals transmitted through the conductive lines. In particular, the use is suitable for display panels. Particularly, in the form of connecting of the conductive lines from both sides of the display area 1d as shown in FIG. 1, it is possible to draw the conductive lines substantially in lines symmetry. Therefore, forming the conductive lines is hardly biased over the used area, and it is significantly convenient in respect of maintaining the thickness of the liquid crystal layer at a uniform value in a liquid crystal display panel.

It should be noted that although the above-mentioned embodiments are described about liquid crystal display panels, the present invention is not limited to such panels, and needless to say, the invention is applicable to other types of display devices and various electronic devices. Further, the above-mentioned embodiments are described about the form where the bending angles of the conductive lines are right angles, but the present invention is applicable to other forms (in other words, forms where the conductive lines bend at angles except the right angles).

Furthermore, the above-mentioned embodiments are described about the case where the display area is a rectangle, but the present invention is not limited to such a case. Moreover, although the conductive lines are connected to gate electrode lines as an example, the conductive lines may be connected to source electrode lines. The present invention is applicable to display devices other than the active matrix driving type display device.

In the foregoing, several representative embodiments according to the present invention are described, but those skilled in the art can modify the embodiments in various manners as necessary without departing from the scope of the claims.

### INDUSTRIAL APPLICABILITY

The present invention is applicable to electronic devices having bending wiring patterns.

1. An electronic device having a substrate on which a plurality of conductive lines are formed, the conductive lines having such patterns that the lines are straightly extended from their predetermined front ends and thereafter bend by turns in substantially the same direction for each predetermined interval to further extend to the respective predetermined connection targets, wherein
the conductive lines have their straightly-extending portions of varied line widths and a line width at a nearer position to a bending point of the line is made larger than a line width at a farther position from the bending point, so as to equalize at least resistance values of the straightly-extending portions of the conductive lines.

2. An electronic device as defined in claim 1, wherein the front ends of the conductive lines are connected to inputs/outputs of driving circuitry or peripheral circuitry of the electronic device.

3. An electronic device as defined in claim 1, wherein the connection targets of the conductive lines are a plurality of lines extending substantially in parallel to each other at predetermined intervals.

4. An electronic device as defined in claim 1, wherein the bending angle is substantially a right angle.

5. An electronic device as defined in claim 1, comprising a plurality of bus lines extending in parallel to each other at predetermined intervals in a display area defined by at least one and the other sides opposed to each other, the bus lines extending from a position of the one side to a position of the other side, wherein the straightly-extending portions are arranged in an area outside the display area adjacent to at least one of the one and the other sides.

6. An electronic device as defined in claim 5, wherein the bus lines are row electrode lines or gate electrode lines, or column electrode lines or source electrode lines.

7. An electronic device as defined in claim 5, wherein the display area is also defined by third and fourth sides opposed to each other and formed substantially perpendicularly to the one and the other sides, and the driving circuitry or peripheral circuitry is provided in an area outside the display area adjacent to at least one of the third and fourth sides.
